(19) United States
(12) Patent Application Publication
(10) Pub. No.: US 2025/0311530 A1
(43) Pub. Date: Oct. 2, 2025

(54) LIGHT-EMITTING ELEMENT, DISPLAY DEVICE, METHOD FOR MANUFACTURING LIGHT-EMITTING ELEMENT, AND METHOD FOR MANUFACTURING DISPLAY DEVICE

(71) Applicant: Sharp Display Technology Corporation, Kameyama City, Mie (JP)

(72) Inventors: Yusuke SAKAKIBARA, Kameyama City, Mie (JP); Yoshihiro UETA, Kameyama City, Mie (JP)

(21) Appl. No.: 18/855,707

(22) PCT Filed: Jun. 3, 2022
(86) PCT No.: PCT/JP2022/022592

§ 371 Date: Oct. 10, 2024

(51) Int. Cl. H10K 50/115; H10K 50/125

(52) U.S. Cl. CPC H10K 50/115; H10K 50/125

(57) ABSTRACT

A light-emitting element includes a first electrode, a second electrode, and a light-emitting layer including a plurality of quantum dots, the light-emitting layer has a first region in which a first light-emitting layer is provided and a second region in which a second light-emitting layer is provided when viewed in a layering direction that is a direction from the first electrode to the second electrode, the density of the quantum dots in the second light-emitting layer is lower than the density of the quantum dots in the first light-emitting layer, and in the second light-emitting layer, spaces between the plurality of quantum dots are filled with an inorganic compound.

### TECHNICAL FIELD

The disclosure relates to a light-emitting element including quantum dots, a display device including the light-emitting element as a light-emitting element, and a method for manufacturing these.

### BACKGROUND ART

PTL 1 discloses a light-emitting element including a light-emitting layer having semiconductor nanocrystals (quantum dots) as a light-emitting material.

### CITATION LIST

### Patent Literature

PTL 1: JP 2007-95685 A

### SUMMARY OF INVENTION

### Technical Problem

When foreign matters such as moisture or air enter a light-emitting layer including quantum dots as a light-emitting material, the foreign matters may propagate between a plurality of quantum dots and permeate the entire light-emitting layer. This causes deterioration of many quantum dots in the light-emitting layer, leading to a decrease in the luminous efficiency of the light-emitting element.

In order to prevent the propagation of the foreign matters between the quantum dots, it is conceivable to reduce the density of the quantum dots in the light-emitting layer. In this case, it becomes difficult for carriers injected into the quantum dots to be transported via the quantum dots, so the luminous efficiency of the light-emitting layer decreases or the voltage applied to the light-emitting element required for obtaining a predetermined luminance increases.

### Solution to Problem

A light-emitting element according to an aspect of the disclosure includes a first electrode, a second electrode, and a light-emitting layer including a plurality of quantum dots between the first electrode and the second electrode, in which the light-emitting layer has a first region in which a first light-emitting layer is provided and a second region in which a second light-emitting layer is provided when viewed in a layering direction that is a direction from the first electrode to the second electrode, a density of the plurality of quantum dots in the second light-emitting layer is lower than a density of the plurality of quantum dots in the first light-emitting layer, and in the second light-emitting layer, spaces between the plurality of quantum dots are filled with an inorganic matrix.

A display device according to an aspect of the disclosure includes a substrate, and a red light-emitting element, a green light-emitting element, and a blue light-emitting element on the substrate, in which each of the red light-emitting element, the green light-emitting element, and the blue light-emitting element is the light-emitting element according to the aspect of the disclosure.

A method for manufacturing a light-emitting element according an aspect of the disclosure is a method for manufacturing a light-emitting element that includes a first electrode, a second electrode, and a light-emitting layer including a plurality of quantum dots between the first electrode and the second electrode, the method including forming the light-emitting layer having a first region in which a first light-emitting layer is provided and a second region in which a second light-emitting layer is provided when viewed in a layering direction that is a direction from the first electrode to the second electrode, in which a density of the plurality of quantum dots in the second light-emitting layer is lower than a density of the plurality of quantum dots in the first light-emitting layer, and in the second light-emitting layer, spaces between the plurality of quantum dots are filled with an inorganic matrix.

A method for manufacturing a display device according to an aspect of the disclosure includes preparing a substrate having a plurality of subpixel regions, and forming, by the method for manufacturing a light-emitting element according to an aspect of the disclosure, the light-emitting element in each of the plurality of subpixel regions on the substrate.

### Advantageous Effects of Invention

To reduce a decrease in luminous efficiency of a light-emitting element as a whole due to mixing of foreign matters into a light-emitting layer while reducing an increase in applied voltage required for obtaining predetermined luminance.

### BRIEF DESCRIPTION OF DRAWINGS

FIG. 1 is a cross-sectional view of a light-emitting element according to a first embodiment.

FIG. 2 is a cross-sectional view illustrating operation of the light-emitting element.

FIG. 3 is another cross-sectional view illustrating the operation of the light-emitting element.

FIG. 4 is a cross-sectional view of a light-emitting element according to a comparative example.

FIG. 5 is a cross-sectional view illustrating the operation of the light-emitting element layer.

FIG. 6 is another cross-sectional view illustrating the operation of the light-emitting element.

FIG. 7 is a graph depicting the relationship between voltage and luminance for the operation of the light-emitting element according to the first embodiment.

FIG. 8 is a cross-sectional view illustrating the operation of the light-emitting element in the absence of foreign matters.

FIG. 9 is a graph depicting the relationship between voltage and luminance for the operation of the light-emitting element in the absence of foreign matters.

FIG. 10 is a cross-sectional view illustrating the operation of the light-emitting element in the presence of foreign matters.

FIG. 11 is a graph depicting the relationship between voltage and luminance related to the operation of the light-emitting element in the presence of foreign matters.

FIG. 12 is a schematic view for explaining an image displayed on a screen by a light-emitting element according to a comparative example.

FIG. 13 is a schematic view for explaining an image displayed on a screen by the light-emitting element according to the first embodiment.

FIG. 14 is a schematic view for explaining an image displayed on a screen by a light-emitting element according to another comparative example.

FIG. 15 is a diagram for explaining the density of quantum dots formed in a first region provided in the light-emitting layer of the light-emitting element according to the first embodiment.

FIG. 16 is a diagram for explaining the density of quantum dots formed in a second region provided in the light-emitting layer.

FIG. 17 is a cross-sectional view of a light-emitting element according to a modified example of the first embodiment.

FIG. 18 is a graph depicting the relationship between voltage and luminance for the operation of the light-emitting element.

FIG. 19 is a cross-sectional view illustrating the operation of the light-emitting element in the absence of foreign matters.

FIG. 20 is a graph depicting the relationship between voltage and luminance for the operation of the light-emitting element in the absence of foreign matters.

FIG. 21 is a cross-sectional view illustrating the operation of the light-emitting element in the presence of foreign matters.

FIG. 22 is a graph depicting the relationship between voltage and luminance for the operation of the light-emitting element in the presence of foreign matters.

FIG. 23 is a cross-sectional view illustrating a method for manufacturing the light-emitting element according to the first embodiment.

FIG. 24 is a cross-sectional view illustrating the method for manufacturing the light-emitting element.

FIG. 25 is a cross-sectional view illustrating the method for manufacturing the light-emitting element.

FIG. 26 is a cross-sectional view illustrating the method for manufacturing the light-emitting element.

FIG. 27 is a cross-sectional view illustrating the method for manufacturing the light-emitting element.

FIG. 28 is a cross-sectional view illustrating the method for manufacturing the light-emitting element.

FIG. 29 is a cross-sectional view illustrating the method for manufacturing the light-emitting element.

FIG. 30 is a plan view of a display device according to the first embodiment.

FIG. 31 is a plan view of a display device according to a modified example of the first embodiment.

FIG. 32 is a plan view of a display device according to another modified example of the first embodiment.

FIG. 33 is a graph depicting energy levels of a red light-emitting element, a green light-emitting element, and a blue light-emitting element provided in the display device.

FIG. 34 is a plan view of a display device according to a second embodiment.

FIG. 35 is a schematic view illustrating an average density of quantum dots in a plurality of divided regions of a light-emitting layer of a light-emitting element according to a third embodiment.

FIG. 36 is a histogram illustrating the average density of the quantum dots.

FIG. 37 is a schematic view illustrating another average density of the quantum dots.

FIG. 38 is a histogram illustrating another average density of the quantum dots.

FIG. 39 is a schematic view illustrating still another average density of the quantum dots.

FIG. 40 is a histogram illustrating still another average density of the quantum dots.

FIG. 41 is a schematic view illustrating still another average density of the quantum dots.

FIG. 42 is a histogram illustrating still another average density of the quantum dots.

### DESCRIPTION OF EMBODIMENTS

### First Embodiment

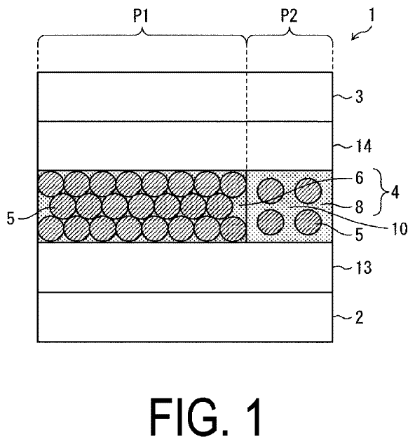

FIG. 1 is a cross-sectional view of a light-emitting element 1 according to a first embodiment. The light-emitting element 1 includes a first electrode 2, a second electrode 3, and a light-emitting layer 4 including a plurality of quantum dots (QDs) 5 between the first electrode 2 and the second electrode 3. The first electrode 2 may be an anode electrode. The second electrode 3 may be a cathode electrode. A hole transport layer 13 may be formed between the light-emitting layer 4 and the first electrode 2. An electron transport layer 14 may be formed between the light-emitting layer 4 and the second electrode 3.

In this specification, the term “quantum dot” refers to a dot having a maximum width of 100 nm or less. The shape of the quantum dot is not particularly limited as long as it is within a range satisfying the maximum width, and the shape is not limited to a spherical three-dimensional shape (circular cross-sectional shape). The shape of the quantum dot may be, for example, a polygonal cross-sectional shape, a rod-like three-dimensional shape, a branch-like three-dimensional shape, or a three-dimensional shape having unevenness on the surface, or a combination thereof.

The quantum dot typically may be composed of a semiconductor. The semiconductor may have a constant band gap. The semiconductor may be a material capable of emitting light and may include at least a material which will be described below. The semiconductor may emit each of red light, green light, and blue light. The semiconductor includes, for example, at least one kind selected from the group consisting of a group II-VI compound, a group III-V compound, and a chalcogenide and a perovskite compound. Note that the group II-VI compound refers to a compound including a group II element and a group VI element, and the group III-V compound refers to a compound including a group III element and a group V element. Further, the group II element may include a group 2 element and a group 12 element, the group III element may include a group 3 element and a group 13 element, the group V element may include a group 5 element and a group 15 element, and the group VI element may include a group 6 element and a group 16 element.

Examples of the group II-VI compound include, for example, at least one kind selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

Examples of the group III-V compound include, for example, at least one kind selected from the group consisting of GaAs, GaP, InN, InAs, InP, and InSb.

The chalcogenide is a compound including a group VI A (16) element, and includes, for example, CdS or CdSe. The chalcogenide may include a mixed crystal thereof.

The perovskite compound has, for example, a composition represented by a general formula CsPbX₃. Examples of the constituent element X include at least one kind selected from the group consisting of Cl, Br, and I.

Here, the numbering of groups of an element by using Roman numerals is numbering based on the old International Union of Pure and Applied Chemistry (IUPAC) system or old Chemical Abstracts Service (CAS) system, and the numbering of groups of an element by using Arabic numerals is numbering based on the current IUPAC system.

The light-emitting layer 4 has a first region P1 in which a first light-emitting layer 6 is provided and a second region P2 in which a second light-emitting layer 8 is provided, when viewed in the layering direction that is a direction from the first electrode 2 to the second electrode 3. That is, when the light-emitting layer 4 is cut along a plane parallel to the layering direction as illustrated in FIG. 1, the cross section of the light-emitting layer 4 has the first region P1 in which the first light-emitting layer 6 is provided and the second region P2 in which the second light-emitting layer 8 is provided. Note that the cut surface can be selected from any surface parallel to the layering direction, and it is only necessary to confirm that the light-emitting layer 4 has the first region P1 in which the first light-emitting layer 6 is provided and the second region P2 in which the second light-emitting layer 8 is provided in at least one cross section.

The density of the quantum dots 5 in the second light-emitting layer 8 is lower than the density of the quantum dots 5 in the first light-emitting layer 6.

In the second light-emitting layer 8, spaces between the plurality of quantum dots 5 are filled with an inorganic compound 10. The inorganic compound 10 is composed of an inorganic matrix.

In this specification, the term “inorganic matrix” refers to a member that is made of an inorganic material and contains and holds other materials. That is, the inorganic matrix herein refers to a member that is made of an inorganic material and contains and holds the quantum dots 5. The inorganic matrix is an element constituting the film in which the quantum dots are distributed.

The inorganic matrix is desirably filled in the light-emitting layer 4. The inorganic matrix preferably fills a region other than the quantum dots 5 in the light-emitting layer 4. The inorganic matrix preferably infills a region other than the quantum dots 5 in the light-emitting layer 4. Note that the outer edge of the light-emitting layer 4 does not need to be formed of only the inorganic matrix, and it does not exclude the quantum dots 5 being partially exposed from the inorganic matrix.

The inorganic matrix may be a portion of the light-emitting layer 4 excluding the quantum dots 5.

The inorganic matrix may include the plurality of quantum dots 5. The inorganic matrix may be formed so as to fill spaces formed between the plurality of quantum dots 5. The inorganic matrix may partially or completely fill spaces between the quantum dots 5.

The inorganic matrix desirably includes a continuous film having an area equal to or larger than 1000 nm² in a plane direction orthogonal to the film thickness direction. The continuous film means a region that is not separated by a material other than a material constituting the continuous film in one plane.

The same material as the shell material of the quantum dots 5 may be used for the inorganic matrix. In this case, an average distance between adjacent cores (core-to-core distance) may be equal to or greater than 3 nm or may be equal to or greater than 5 nm. Alternatively, the average distance between adjacent cores may be 0.5 times or more the average core diameter. The core-to-core distance is obtained by averaging the shortest distances between 20 adjacent cores in the cross-sectional observation. The core-to-core distance may be kept wider than the distance when the shell materials are in contact with each other. The average core diameter is obtained by averaging the core diameters of 20 adjacent cores in the cross-sectional observation. The core diameter can be the diameter of a circle having the same area as the core area in the cross-sectional observation.

The concentration of the inorganic matrix in the light-emitting layer 4 may be equal to or greater than 9% and equal to or less than 70% when measured from an area ratio in image processing in the cross-sectional observation. In addition, when the quantum dots 5 have a core/shell structure, the concentration of the shell may be equal to or greater than 0% and equal to or less than 58%. In addition, when the shell material and the inorganic matrix material are the same (the constituent elements are the same), it is substantially difficult to distinguish between the shell and the inorganic matrix. Therefore, the concentration of the region including the inorganic matrix and the shell may be in a numerical range obtained by adding the numerical range of the concentration of the shell to the numerical range of the concentration of the inorganic matrix.

The inorganic matrix is preferably solid at room temperature.

The light-emitting layer 4 may be composed of the quantum dots 5 and an inorganic matrix. The intensity of the chain structure of carbon detected when the light-emitting layer 4 is analyzed may be equal to or less than noise level. When the light-emitting layer 4 does not contain an organic ligand, the strength of the chain structure of carbon to be detected is as weak as noise or less.

The inorganic material constituting the inorganic matrix desirably has a band gap wider than the band gap of the constituent material of the quantum dots 5. The inorganic material constituting the inorganic matrix may be a semiconductor material or an insulator material. The inorganic material constituting the inorganic matrix may be a sulfide semiconductor.

The inorganic material constituting the inorganic matrix includes, for example, a metal sulfide and/or a metal oxide. The metal sulfide may be, for example, zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium sulfide (MgGa₂S₄). The metal oxide may be zinc oxide (ZnO), titanium oxide (TiO₂), tin oxide (SnO₂), tungsten oxide (WO₃), and zirconium oxide (ZrO₂). Note that a chemical formula written within parentheses after a compound name is a representative example. In addition, the composition ratio described in the chemical formula is desirably stoichiometry in which the actual composition of the compound is the same as the chemical formula but is not necessarily stoichiometry.

It is to be noted that the structure of the inorganic matrix described above need not be observed over the entire area of the light-emitting layer 4 as long as the structure described above is obtained by observing the cross section of the light-emitting layer 4 in the range of about 100 nm.

In addition, the main material of the inorganic matrix may be an inorganic material, and a material different from the main inorganic material may be added as an additive.

In the second light-emitting layer 8, spaces between the plurality of quantum dots 5 may be further filled with an organic compound. In the first light-emitting layer 6, spaces between the plurality of quantum dots 5 may be filled with the inorganic compound 10 or an organic compound.

In a display including a Light Emitting Diode (LED) element having the quantum dots 5, a pixel may not emit light due to foreign matters including oxygen and water.

When the density of the quantum dots 5 is high, since the substantial thickness of the medium (or inorganic medium) for protecting the surface defects of the quantum dots 5 is small, the surfaces of the quantum dots 5 have high activity for easy reaction, and the number of quantum dots 5 entering a certain volume in which oxygen or water diffuses increases. For this reason, when the foreign matters including oxygen or water enter a pixel at the time of manufacturing a display, the quantum dots 5 are oxidized in a chain reaction manner, and the entire pixel may not emit light. That is, a dark spot is generated in the image display of the display. On the other hand, when the density of the quantum dots 5 is reduced, since the thickness of the inorganic medium around the quantum dots 5 is increased, it is difficult to inject current, the luminous efficiency is reduced, and the power consumption of the entire display is increased, so the density of the quantum dots 5 in the entire pixel cannot be reduced.

Therefore, in the first embodiment, the second region P2 in which the density of the quantum dots 5 is low is provided in the layering plane of the light-emitting layer 4 of each pixel in the display.

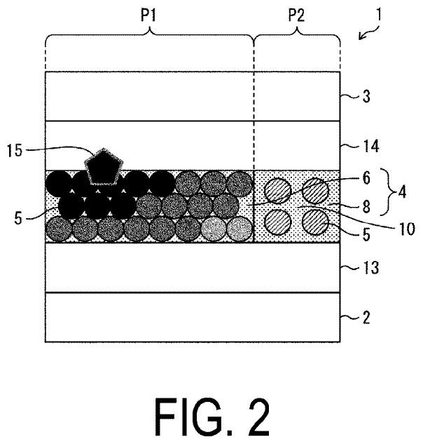

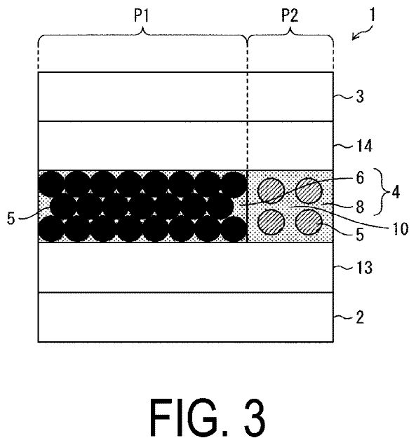

FIG. 2 is a cross-sectional view illustrating operation of the light-emitting element 1. FIG. 3 is another cross-sectional view illustrating the operation of the light-emitting element 1.

In the second region P2 in which the second light-emitting layer 8 is provided and a QD density is low, the inorganic medium containing the inorganic compound 10 for protecting the QD surface defects of the quantum dots 5 is substantially thick. For this reason, in the second region P2, the QD surfaces have lower activity and low reactivity, and the number of quantum dots 5 entering a certain volume in which oxygen or water diffuses is small. Therefore, even when foreign matters 15 containing oxygen or water enter the light-emitting layer 4 as illustrated in FIG. 2, oxidation of the quantum dots 5 in the second region P2 is not likely to proceed as illustrated in FIG. 3 even when oxidation of the quantum dots 5 in the first region P1 is advanced. Here, the darker the color of the hatching of the quantum dots 5 shown in FIG. 2 and FIG. 3, the more advanced the oxidation. The same applies to the drawings that will be described later.

On the other hand, since the density of the quantum dots 5 is higher in the first region P1 in which the first light-emitting layer 6 is provided than in the second region P2, current injection into the first light-emitting layer 6 becomes easier, and the drive voltage of the first light-emitting layer 6 decreases. Therefore, the light-emitting element 1 according to the present embodiment can reduce an increase in power consumption by the first light-emitting layer 6 and can reduce the possibility of becoming a non-light-emitting element due to entry of foreign matters by the second light-emitting layer 8.

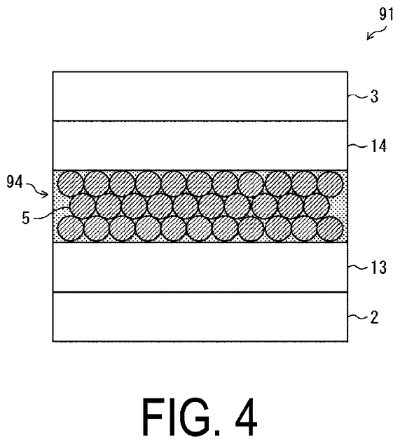

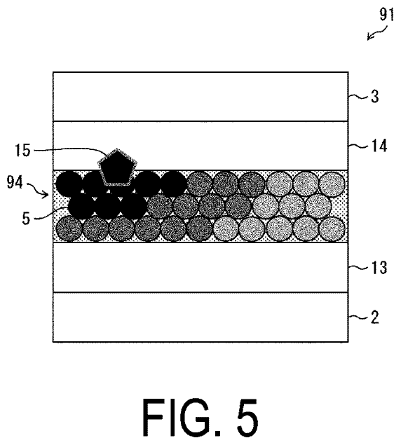

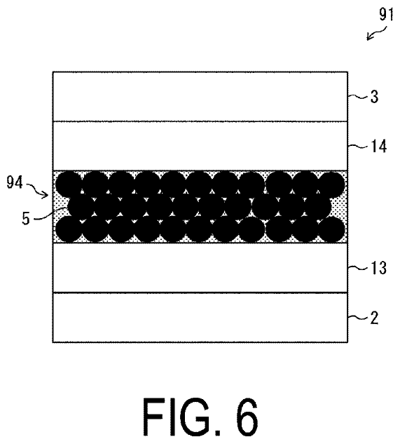

FIG. 4 is a cross-sectional view of a light-emitting element 91 according to the comparative example. FIG. 5 is a cross-sectional view illustrating the operation of the light-emitting element 91. FIG. 6 is another cross-sectional view illustrating the operation of the light-emitting element 91. The same components as the above-described components are denoted by the same reference numerals, and detailed description of the components is not repeated.

The light-emitting element 91 includes the first electrode 2, the second electrode 3, and a light-emitting layer 94 having the plurality of quantum dots 5 between the first electrode 2 and the second electrode 3. The light-emitting layer 94 corresponds to the first light-emitting layer 6 described above with reference to FIG. 1.

The quantum dots 5 are nano-sized and have high activity and reactivity. When the density of the quantum dots 5 is high, the substantial thickness of the inorganic medium that protects the surface defects of the quantum dots 5 is small. Therefore, the surfaces of the quantum dots 5 have high activity for easy reaction, and the number of quantum dots 5 entering a certain volume in which oxygen or water diffuses is large. Therefore, as illustrated in FIG. 5, when the foreign matters 15 containing oxygen or water enter the light-emitting layer 94, the quantum dots 5 are oxidized in a chain reaction manner, and as illustrated in FIG. 6, the entire pixel of the light-emitting element 91 does not emit light.

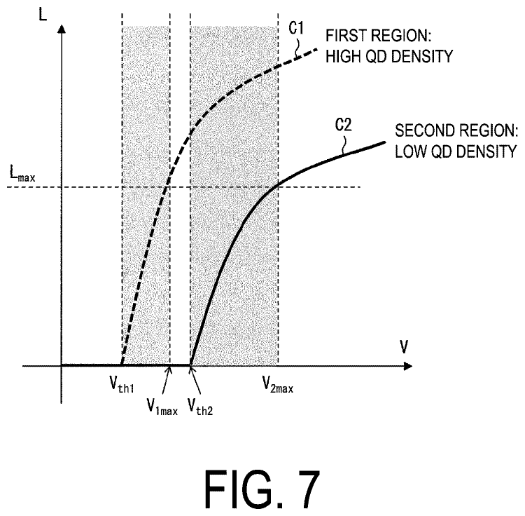

FIG. 7 is a graph depicting the relationship between voltage and luminance for the operation of the light-emitting element 1. The horizontal axis represents voltage applied between the first electrode 2 and the second electrode 3 of the light-emitting element 1 in order to cause the light-emitting element 1 to emit light. The vertical axis represents the luminance of the light-emitting element 1 that emits light by the voltage.

A curved line C1 indicates the voltage-luminance characteristics of the quantum dots 5 in the first region P1 in which the QD density of the light-emitting layer 4 is high. A curved line C2 indicates the voltage-luminance characteristics of the quantum dots 5 in the second region P2 in which the QD density of the light-emitting layer 4 is low.

As indicated by the curved line C1, a voltage V for driving the quantum dots 5 in the first region P1 is equal to a voltage Vₜₕ₁ when the luminance L is 0, and is equal to a voltage V₁ₘₐₓ when the luminance L is Lₘₐₓ.

In the second region P2, the density of the quantum dots 5 is made lower than that in the first region P1 to strengthen the protection of the quantum dots 5, but on the other hand, the current injection becomes difficult and the voltage V becomes high.

As indicated by the curved line C2, the voltage V for driving the quantum dots 5 in the second region P2 is a voltage Vₜₕ₂ higher than the voltage Vₜₕ₁ when the luminance L is 0, and is a voltage V₂ₘₐₓ when the luminance L is Lₘₐₓ.

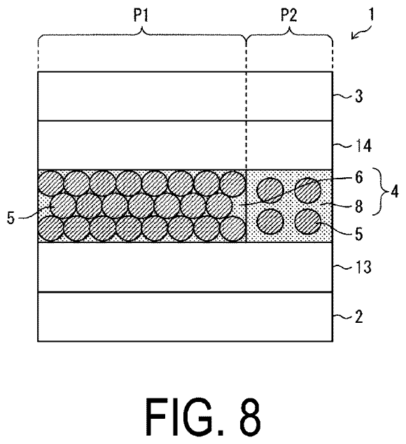

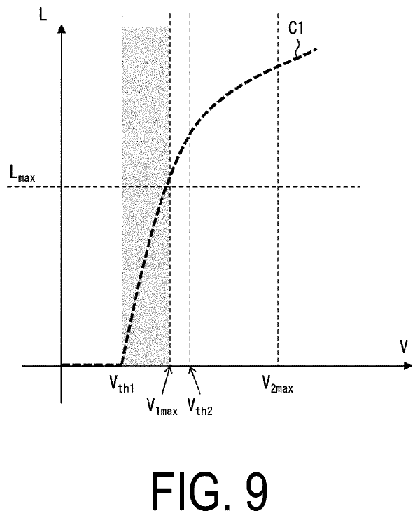

FIG. 8 is a cross-sectional view illustrating the operation of the light-emitting element 1 in the absence of the foreign matters 15. FIG. 9 is a graph depicting the relationship between voltage and luminance for the operation of the light-emitting element 1 in the absence of the foreign matters 15. The same components as the above-described components are denoted by the same reference numerals, and detailed description of the components is not repeated.

When the foreign matters 15 do not enter the light-emitting layer 4, the light-emitting element 1 is driven only in the range of the voltage from Vₜₕ₁ to V₁ₘₐₓ in which the quantum dots 5 included in the first region P1 emit light. Therefore, the quantum dots 5 included in the second region P2 in which the emission threshold value is Vₜₕ₂ (>V₁ₘₐₓ) do not emit light.

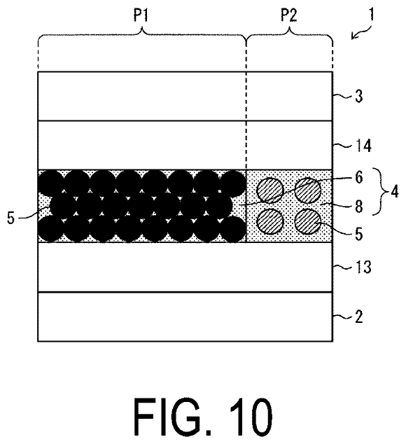

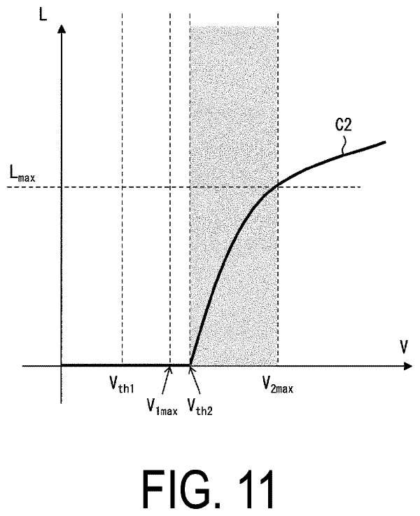

FIG. 10 is a cross-sectional view illustrating the operation of the light-emitting element 1 in the presence of the foreign matters 15. FIG. 11 is a graph depicting the relationship between voltage and luminance for the operation of the light-emitting element 1 in the presence of the foreign matters 15. The same components as the above-described components are denoted by the same reference numerals, and detailed description of the components is not repeated.

When the foreign matters 15 enter the light-emitting layer 4, the oxidation of the quantum dots 5 in the first region P1 is likely to proceed. Therefore, the electron levels of the surfaces (and the interiors) of the quantum dots 5 in at least the first region P1 are greatly changed, and current is less likely to be injected into the carrier-transport layer that matches the electron levels of the unoxidized quantum dots 5, in other words, current is less likely to flow in the first region P1. Therefore, in the case described above, current is injected only into the second region P2. That is, by driving the light-emitting element 1 in the voltage range from Vₜₕ₂ to V₂ₘₐₓ, the quantum dots 5 included in the second region P2 of the light-emitting layer 4 are caused to emit light.

As a specific driving method, after a display including the light-emitting element 1 is manufactured, all pixels are driven with the voltage V₁ₘₐₓ for test driving. Then, by finding a non-light-emitting pixel, it is determined that the non-light-emitting pixel has the foreign matters 15, and it is determined that the light-emitting pixel has no foreign matter. Next, the determination result is fed back to the driving unit of the light-emitting element 1. The driving unit drives the non-light-emitting pixel determined to have foreign matters based on the curved line C2 and drives the light-emitting pixel determined to have no foreign matters based on the curved line C1.

This driving method can be implemented within a range of inspection normally performed for correcting luminance variation of pixels in a manufacturing process of a display.

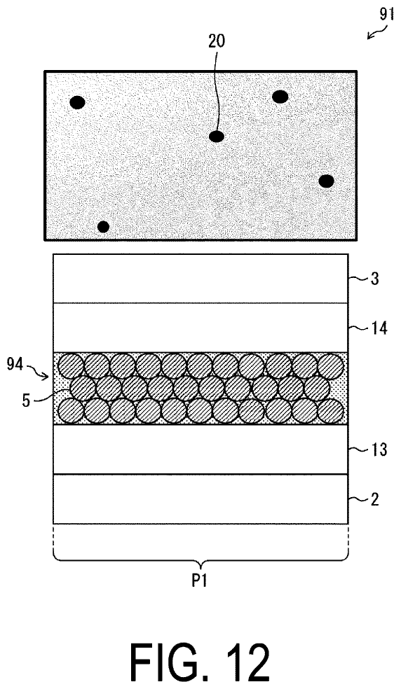

Alternatively, the relationship between the drive current and the luminance may be measured in advance for the first region P1, and both the pixel without the foreign matters 15 and the pixel with the foreign matters 15 may be constant-current-driven with the drive current based on the relationship. The pixel without the foreign matters 15 can emit light at a predetermined luminance. In the pixel with the foreign matters 15, since the area of the second region P2 is smaller than the area of the first region P1, the current density for driving the second region P2 is increased accordingly, so the reduction of the light emitting area due to the light emission of only the second region is automatically compensated and the luminance of the pixel can be maintained at a certain level. Thus, the dark spot 20 (FIG. 12) can be made inconspicuous to human eyes.

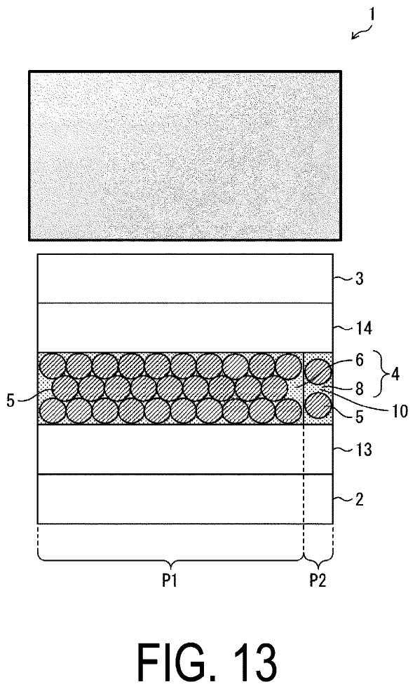

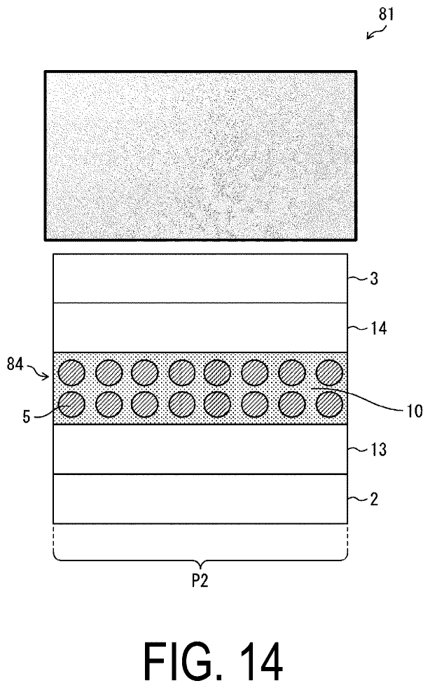

FIG. 12 is a schematic view for explaining an image displayed on a screen by the light-emitting element 91 according to the comparative example. FIG. 13 is a schematic view for explaining an image displayed on a screen by the light-emitting element 1 according to the first embodiment. FIG. 14 is a schematic view for explaining an image displayed on a screen by a light-emitting element 81 according to another comparative example. The same components as the above-described components are denoted by the same reference numerals, and detailed description of the components is not repeated.

In the light-emitting element 91, the light-emitting layer 94 has only the first region P1. In the light-emitting element 81, the light-emitting layer 84 has only the second region P2.

TABLE 1

| | | Light-emitting | |
|---|---|---|---|
| | | element 1 | |
| | | Area ratio of | |
| | Light-emitting | second region: | Light-emitting |
| | element 91 | 0.1 | element 81 |
| Power consumption | 100% | 111% | 200% |
| Non-light-emitting | Yes | None | None |
| pixel | | | |

As shown in Table 1, the power consumption of the display including the light-emitting element 91 in which the light-emitting layer 94 has only the first region P1 is assumed to be 100%. In this light-emitting element 91, since the inorganic medium portion becomes thin, a non-light-emitting pixel occurs due to QD deterioration caused by the foreign matters 15 as illustrated in FIG. 12.

In the case of the light-emitting element 81 in which the light-emitting layer 84 has only the second region P2, current injection is difficult due to the low density of the quantum dots 5, so the luminous efficiency is reduced (half of the luminous efficiency of the light-emitting element 91 having only the first region P1) and the power consumption of the display is 200%. On the other hand, the inorganic compound 10 in the inorganic medium portion is thick, and the protection of the quantum dots 5 becomes strong. Therefore, since the deterioration of the quantum dots 5 due to the foreign matters 15 does not occur, the non-light-emitting pixel are not generated as illustrated in FIG. 14.

In the light-emitting element 1 according to the first embodiment, only the first region P1 (area ratio 0.9) is caused to emit light in the pixel without the foreign matters 15. The second region P2 does not contribute to light emission. For this reason, since the drive current of the first region P1 is increased (1/0.9 times) so as to obtain the same luminance as that of the light-emitting element 91 having only the first region P1, the power consumption of the light-emitting element 1 increases more than that of the light-emitting element 91.

In the pixel having the foreign matters 15, the first region P1 does not emit light because the protection of the quantum dots 5 is weak. As such, driving is performed only in the second region P2 (area ratio 0.1). Therefore, although the current for driving the pixel increases (1/0.1×2=20 times), since the number of pixels having the foreign matters 15 is extremely smaller than that of pixels without the foreign matters 15, the current does not contribute to the power consumption of the entire display.

In order to set the power consumption of the display according to the present embodiment to 150% or less, the area ratio of the second region P2 may be set to 0.33 or less. In addition, the area ratio of the second region P2 is desirably 0.1 or more in order to secure the light emission luminance of the pixel having the foreign matters 15.

That is, it is preferable that the area ratio of the second region P2 to the total of the area of the first region P1 and the area of the second region P2 be 10% or more and 33% or less. For example, in any one of cross sections along the layering direction of the light-emitting layer 4, the area of the second region P2 is preferably 10% or more and 33% or less of the total area of the first region P1 and the second region P2.

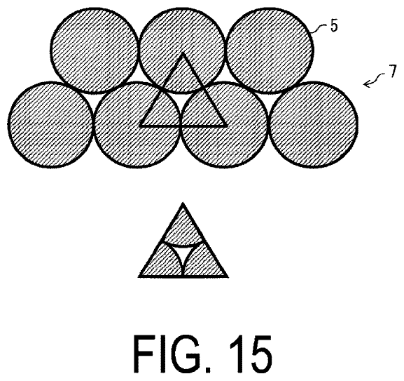

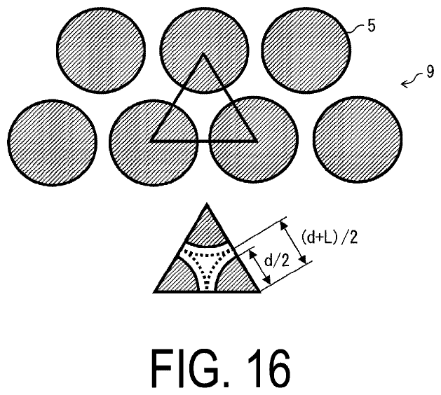

FIG. 15 is a diagram for explaining the density of the quantum dots 5 formed in the first region P1 provided in the light-emitting layer 4 of the light-emitting element 1. FIG. 16 is a diagram for explaining the density of the quantum dots 5 formed in the second region P2 provided in the light-emitting layer 4.

The configuration of the light-emitting element 1 according to the first embodiment can be verified by cross section al Transmission Electron Microscopy (TEM). The density of the quantum dots 5 can be defined by an area filling rate of any one of cross sections along the layering direction of the light-emitting layer 4 (a ratio of any one of cross-sectional areas of the quantum dots 5 to a total area).

In the case of closest filling (the quantum dots 5 are spherical), the area filling rate is 91%. When the particle diameter of the quantum dots 5 is d (=5 nm) and the distance between the quantum dots 5 is L, the area filling rate is obtained by Expression 1.

$$91 \% \times {( \frac{d}{d + L} )}^{2} \qquad [ Expression 1 ]$$

When a distance L is equal to or greater than 2 nm (ZnS lattice constant 0.5 nm×4 layers) (area filling rate 46% or less), surface defects of the quantum dots 5 are sufficiently protected by the inorganic compound 10, and the quantum dots 5 are not oxidized. In addition, when the area filling rate is 30% or less, current cannot be injected and the quantum dots 5 do not emit light, so the area filling rate of the second region P2 is desirably from 30% to 46%. In order to improve current injection in the first region P1, it is desirable that the distance L be equal to or less than 1 nm (ZnS lattice constant 0.5 nm×2 layers) (area filling rate 63% or more).

From the above, the area filling rate of the first region P1 is preferably from 63% to 91%. In addition, the density of the quantum dots 5 in the second region P2 is preferably from 30% to 46%.

When the shape of the quantum dots 5 is a cube, calculation may be performed, assuming that the diameter d (=5 nm) is the length of one side of the cube and the area filling rate is 100% as in the case of closest filling, resulting in the following range.

That is, the area filling rate of the first region P1 is preferably from 69% to 100%. The density of the quantum dots 5 in the second region P2 is preferably from 30% to 51%.

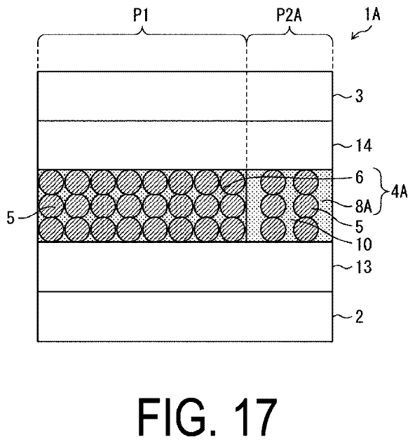

FIG. 17 is a cross-sectional view of a light-emitting element 1A according to a modified example of the first embodiment. The same components as the above-described components are denoted by the same reference numerals, and detailed description of the components is not repeated.

The light-emitting element 1A includes the first electrode 2, the second electrode 3, and a light-emitting layer 4A having the plurality of quantum dots 5 between the first electrode 2 and the second electrode 3. The light-emitting layer 4A has the first region P1 in which the first light-emitting layer 6 is provided and a second region P2A in which a second light-emitting layer 8A is provided when viewed in the layering direction that is the direction from the first electrode 2 to the second electrode 3.

The density of the quantum dots 5 along the layering direction in the second light-emitting layer 8A is the same as the density of the quantum dots 5 along the layering direction in the first light-emitting layer 6. However, the density of the quantum dots 5 along the intersecting direction intersecting the layering direction in the second light-emitting layer 8A is lower than the density of the quantum dots 5 along the intersecting direction in the first light-emitting layer 6.

As described above, in the second region P2A, the QD density along the longitudinal direction is substantially the same as that of the first region P1, and only the QD density along the lateral direction is smaller than that of the first region P1. Water and oxygen originating from the foreign matters diffuse only in the first region P1 and do not diffuse in the second region P2A.

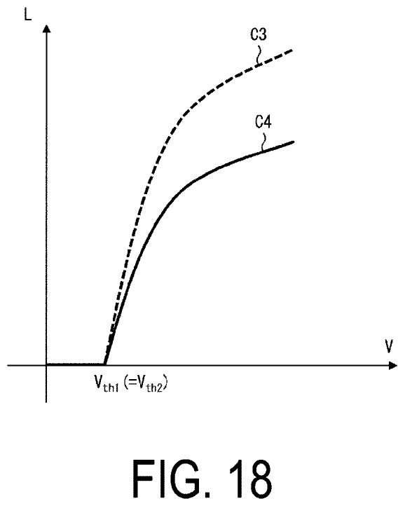

FIG. 18 is a graph depicting the relationship between voltage and luminance for the operation of the light-emitting element 1A. The same components as the above-described components are denoted by the same reference numerals, and detailed description of the components is not repeated.

A curved line C3 indicates the voltage-luminance characteristics of the quantum dots 5 in the first region P1 having a high QD density along the intersecting direction of the light-emitting layer 4A. A curved line C4 indicates the voltage-luminance characteristics of the quantum dots 5 in the second region P2A having a low QD density along the intersecting direction of the light-emitting layer 4A.

Since the first region P1 and the second region P2A have the same QD density in the longitudinal direction, both regions emit light at the emission threshold voltage Vₜₕ₁ (=Vₜₕ₂) as illustrated in FIG. 18. However, since the QD density in the lateral direction is lower in the second region P2A than in the first region P1, the luminance of the quantum dots 5 in the second region P2A indicated by the curved line C4 at the same voltage is lower as illustrated in FIG. 18.

In this way, since the emission threshold voltages can be made the same in the first region P1 and the second region P2A, it is possible to lower the drive voltage of the pixel having foreign matters.

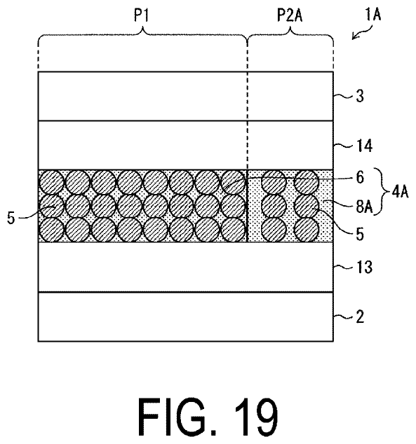

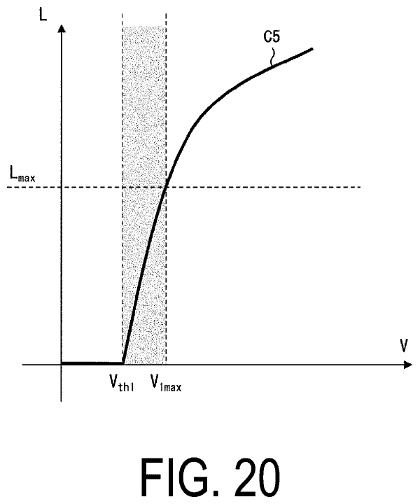

FIG. 19 is a cross-sectional view illustrating the operation of the light-emitting element 1A in the absence of the foreign matters. FIG. 20 is a graph depicting the relationship between voltage and luminance for the operation of the light-emitting element 1A in the absence of the foreign matters. The same components as the above-described components are denoted by the same reference numerals, and detailed description of the components is not repeated.

When the foreign matters 15 do not enter the light-emitting layer 4A, both the first region P1 and the second region P2A are driven in the range from the voltage Vₜₕ₁ to V₁ₘₐₓ. Then, as indicated by a curved line C5, the luminance is the sum of the luminance of the quantum dots 5 in the first region P1 and the luminance of the quantum dots 5 in the second region P2A.

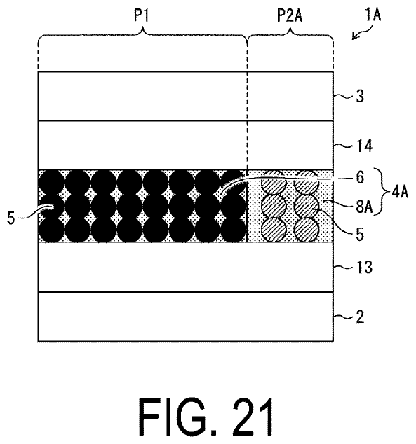

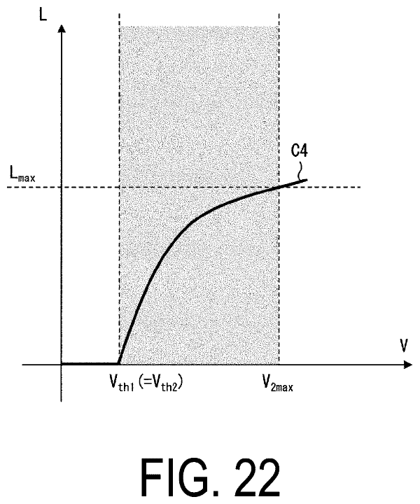

FIG. 21 is a cross-sectional view illustrating the operation of the light-emitting element layer 1A in the presence of foreign matters. FIG. 22 is a graph depicting the relationship between voltage and luminance for the operation of the light-emitting element 1A in the presence of foreign matters. The same components as the above-described components are denoted by the same reference numerals, and detailed description of the components is not repeated.

When the foreign matters 15 enter the light-emitting layer 4, driving is performed only in the second region P2A. By driving in the range from Vₜₕ₂ to V₂ₘₐₓ, the second region P2A is caused to emit light. Since the luminance of the second region P2A is lower than that of the first region P1 at the same voltage, the luminance is compensated by the driving at a high voltage. At this time, the first region P1 does not emit light.

As a driving method, after a display including the light-emitting element 1A is manufactured, all pixels are driven at V₁ₘₐₓ, a pixel whose luminance does not reach Lₘₐₓ is found to determine the presence or absence of foreign matters, and the result is fed back to the driving.

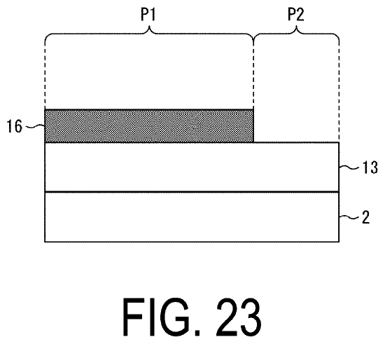

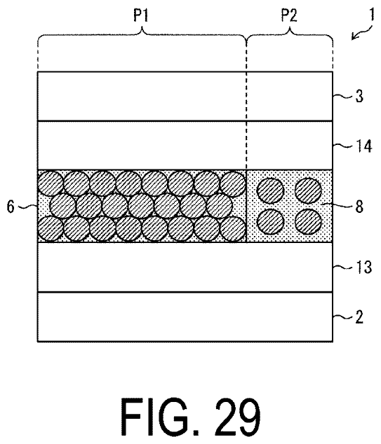

FIG. 23 to FIG. 29 are cross-sectional views each illustrating the method for manufacturing the light-emitting element 1 according to the first embodiment. The same components as the above-described components are denoted by the same reference numerals, and detailed description of the components is not repeated.

First, the portions from the first electrode 2 to the hole transport layer 13 are formed by a general method such as vapor deposition, sputtering, coating, or ink-jet method, and as illustrated in FIG. 23, the portion of the hole transport layer 13 corresponding to the first region P1 is covered with a first resist layer 16.

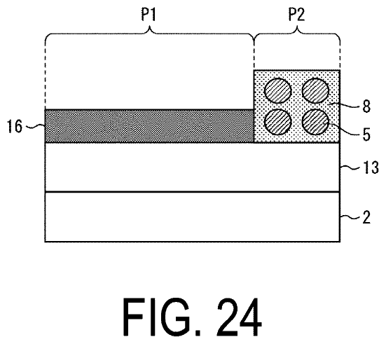

Then, as illustrated in FIG. 24, the second light-emitting layer 8 in the second region P2 is formed by a method such as coating.

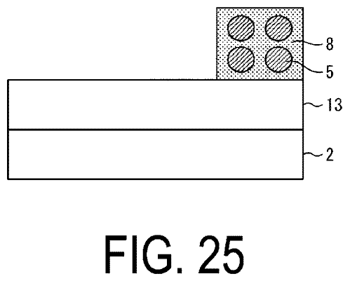

Next, as illustrated in FIG. 25, the first resist layer 16 is removed from the hole transport layer 13.

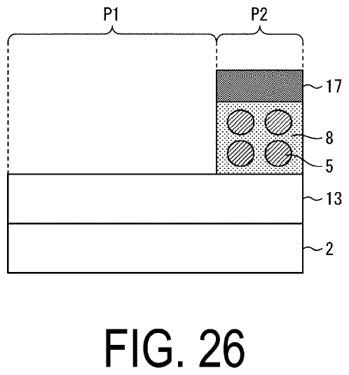

Thereafter, as illustrated in FIG. 26, the second light-emitting layer 8 in the second region P2 is covered with the second resist layer 17. In the second light-emitting layer 8 in the second region P2, since the density of the quantum dots 5 is low and the quantum dots 5 are strongly protected, the quantum dots 5 are less likely to deteriorate due to coating and peeling of the second resist layer 17.

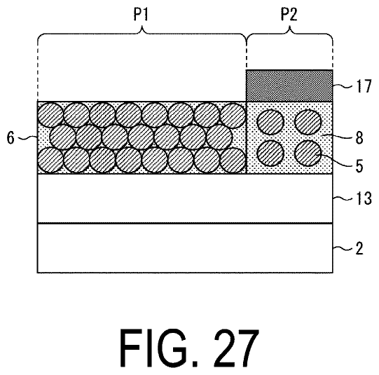

Then, as illustrated in FIG. 27, the first light-emitting layer 6 is formed in the first region P1 by a method such as coating.

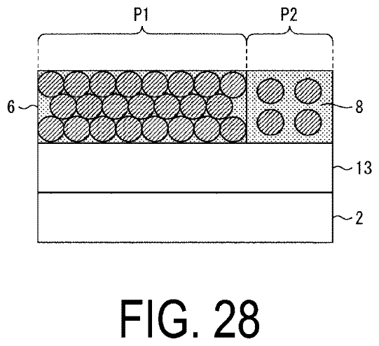

Then, as illustrated in FIG. 28, the second resist layer 17 is removed from the second light-emitting layer 8.

Thereafter, the electron transport layer 14 and the second electrode 3 are formed by a general method such as vapor deposition, sputtering, coating, or ink-jet method to complete the light-emitting element 1.

As the quantum-dot solution for forming the first light-emitting layer 6 in the first region P1 and the quantum-dot solution for forming the second light-emitting layer 8 in the second region P2, the following solutions can be used.

In the case of an inorganic solution, the quantum dots 5 and a ZnS precursor (thiourea zinc or the like) are mixed and applied (solvent: DMF (N, N-dimethylformamide) or the like), and the ZnS precursor is reacted by heating at 250° C. for 30 minutes to form ZnS. Then, by changing the ratio between the quantum dots 5 and the ZnS precursor, the density of the quantum dots 5 in ZnS can be changed.

In the case of an organic solution, a dispersion solution (solvent: hexane, octane, or the like) of the quantum dots 5 having an organic ligand is applied. After the application, heating may be performed to volatilize the solvent.

In this way, by manufacturing the second region P2 before the first region P1, the second light-emitting layer 8 in which the inorganic compound 10 having the protective function is thickly formed is formed before the first light-emitting layer 6. Therefore, the deterioration of the second light-emitting layer 8 caused by the subsequent process is suppressed. In particular, when ZnS of the second light-emitting layer 8 is formed by heating a solution containing a ZnS precursor, because of the above-described manufacturing method, damage due to the heating is less likely to be propagated to the first light-emitting layer 6 and the like.

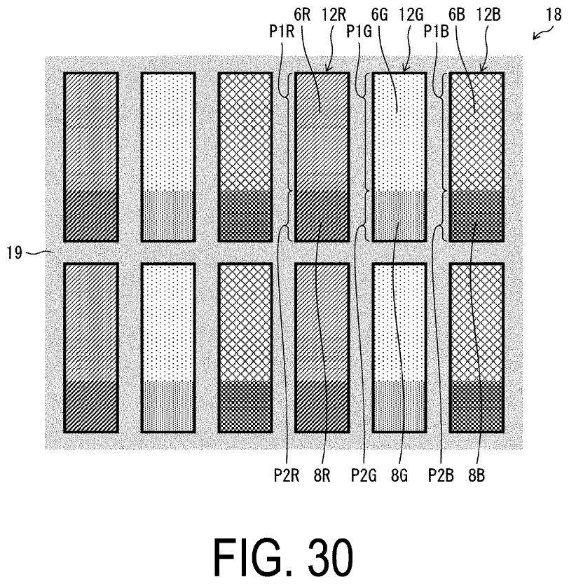

FIG. 30 is a plan view of a display device 18 according to the first embodiment. The same components as the above-described components are denoted by the same reference numerals, and detailed description of the components is not repeated.

The display device 18 includes a substrate 19 and a red light-emitting element 12R, a green light-emitting element 12G, and a blue light-emitting element 12B on the substrate 19. Each of the red light-emitting element 12R, the green light-emitting element 12G, and the blue light-emitting element 12B is configured in the same manner as the light-emitting element 1 described above.

That is, the red light-emitting element 12R has a first light-emitting layer 6R corresponding to a first region PIR in which the density of the quantum dots 5 is high and a second light-emitting layer 8R corresponding to a second region P2R in which the density of the quantum dots 5 is low. The green light-emitting element 12G has a first light-emitting layer 6G corresponding to a first region PIG in which the density of the quantum dots 5 is high and a second light-emitting layer 8G corresponding to a second region P2G in which the density of the quantum dots 5 is low. The blue light-emitting element 12B has a first light-emitting layer 6B corresponding to a first region PIB in which the density of the quantum dots 5 is high and a second light-emitting layer 8B corresponding to a second region P2B in which the density of the quantum dots 5 is low.

The ratio between the area of the first region PIR and the area of the second region P2R, the ratio between the area of the first region PIG and the area of the second region P2G, and the ratio between the area of the first region PIB and the area of the second region P2B are equal to each other.

Each of the light-emitting elements of the display device 18 according to the present embodiment may be manufactured by the same method as the method for manufacturing the light-emitting element 1 according to the present embodiment. Here, in the method for manufacturing the display device 18, the first electrode 2 and the light-emitting layer 4 of the light-emitting element 1 may be formed for each subpixel region of the substrate 19, and the remaining layers each may be formed in common to the plurality of subpixel regions.

In this case, for example, the light-emitting layer 4 of each of the light-emitting elements of the display device 18 may be formed by patterning using a resist. For example, in the method for manufacturing the display device 18 according to the present embodiment, the substrate 19 having a plurality of subpixel regions is prepared, and the first electrode 2 is formed on the substrate 19 for each subpixel region, and the hole transport layer 13 is formed in common to the plurality of subpixel regions. Next, the first resist layer 16 is formed for each subpixel region. Then, the second light-emitting layer 8 is formed in common to a plurality of subpixel regions by the above-described method. Further, the second light-emitting layer 8 is patterned by removing the first resist layer 16. Then, the second resist layer 17 is formed at a position including the upper surface of the second light-emitting layer 8. Further, the first light-emitting layer 6 is formed in common to a plurality of subpixel regions by the above-described method. Then, the first light-emitting layer 6 is patterned by removing the second resist layer 17. Next, the remaining electron transport layer 14 and the second electrode 3 are formed in common to a plurality of subpixel regions. The display device 18 may be manufactured as described above. The patterning of the first light-emitting layer 6 and the second light-emitting layer 8 in each of the light-emitting elements of the display device 18 may be performed for each light-emitting element having the same emission wavelength.

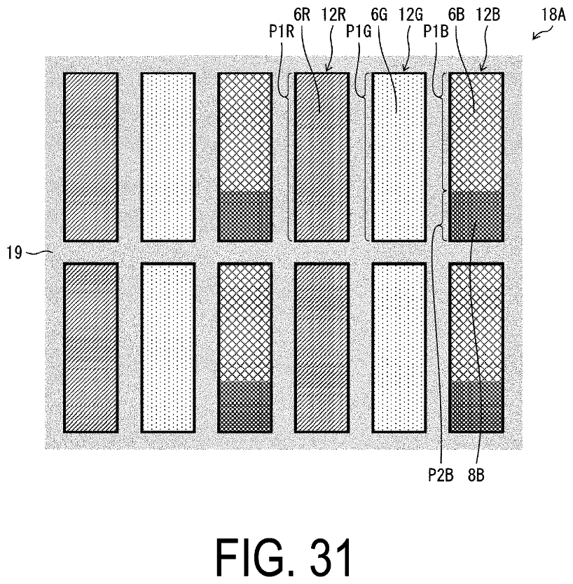

FIG. 31 is a plan view of a display device 18A according to a modified example. The same components as the above-described components are denoted by the same reference numerals, and detailed description of the components is not repeated.

In the display device 18A, of the red light-emitting element 12R, the green light-emitting element 12G, and the blue light-emitting element 12B, only the blue light-emitting element 12B is configured in the same manner as the above-described light-emitting element 1.

That is, the red light-emitting element 12R has only the first region PIR in which the density of the quantum dots 5 is high. The green light-emitting element 12G has only the first region PIG in which the density of the quantum dots 5 is high. The blue light-emitting element 12B has both the first region PIB in which the density of the quantum dots 5 is high and the second region P2B in which the density of the quantum dots 5 is low.

The reason why the second region P2B in which the density of the quantum dots 5 is low is provided only in the blue light-emitting element 12B is that the quantum dots 5 emitting blue light in the blue light-emitting element 12B are more likely to deteriorate due to oxygen or moisture than the quantum dots 5 in the red light-emitting element 12R and the green light-emitting element 12G.

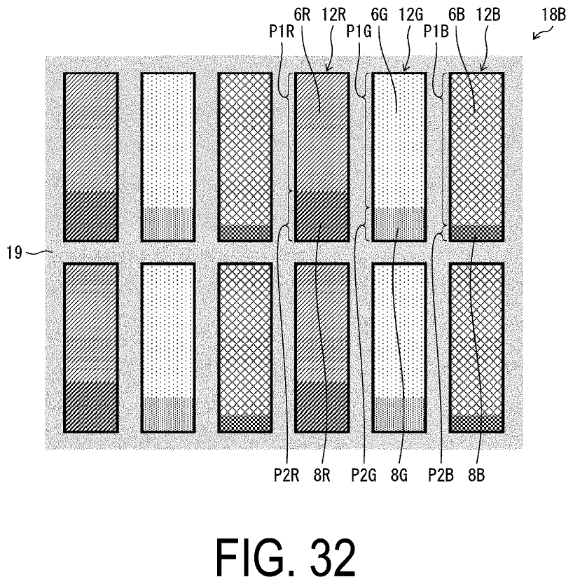

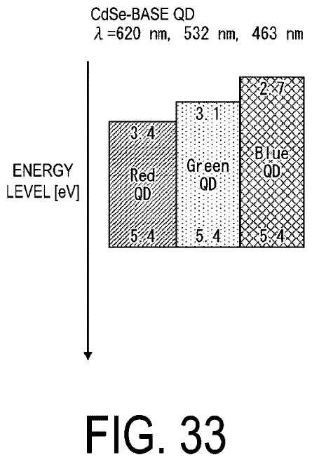

FIG. 32 is a plan view of a display device 18B according to another modified example. FIG. 33 is a graph depicting energy levels of the red light-emitting element 12R, the green light-emitting element 12G, and the blue light-emitting element 12B provided in the display device 18B. The same components as the above-described components are denoted by the same reference numerals, and detailed description of the components is not repeated.

With respect to two light-emitting elements of the red light-emitting element 12R, the green light-emitting element 12G, and the blue light-emitting element 12B, the light-emitting element having the shorter emission wavelength is defined as a short-wavelength element, and the longer emission wavelength is defined as a long-wavelength element. Here, in at least one combination of the short-wavelength element and the long-wavelength element, the cross section of the light-emitting layer 4 of the short-wavelength element is compared with the cross section of the light-emitting layer 4 of the long-wavelength element in any one of cross sections along the layering direction of the short-wavelength element or the long-wavelength element of the display device 18B. In this case, in the cross section, the ratio of the area of the second region P2R, P2G, or P2B to the total area of the light-emitting layer 4 of the short-wavelength element is smaller than the ratio of the area of the second region P2R, P2G, or P2B to the total area of the light-emitting layer 4 of the long-wavelength element.

For example, the red light-emitting element 12R has the first light-emitting layer 6R corresponding to the first region PIR in which the density of the quantum dots 5 is high and the second light-emitting layer 8R corresponding to the second region P2R in which the density of the quantum dots 5 is low. The green light-emitting element 12G has the first light-emitting layer 6G corresponding to the first region PIG in which the density of the quantum dots 5 is high and the second light-emitting layer 8G corresponding to the second region P2G in which the density of the quantum dots 5 is low. The blue light-emitting element 12B has the first light-emitting layer 6B corresponding to the first region PIB in which the density of the quantum dots 5 is high and the second light-emitting layer 8B corresponding to the second region P2B in which the density of the quantum dots 5 is low.

The ratio of the area of the second region P2B to the total area of the first region PIB and the second region P2B is smaller than the ratio of the area of the second region P2G to the total area of the first region PIG and the second region P2G. The ratio of the area of the second region P2G to the total area of the first region PIG and the second region P2G is smaller than the ratio of the area of the second region P2R to the total area of the first region PIR and the second region P2R. That is, the area ratios of the second regions P2R, P2G, and P2B are larger in the order of the second region P2R, the second region P2G, and the second region P2B.

In the case where the hole transport layer (HTL) 13 and the electron transport layer (ETL) 14 are used in common for each color, the shorter the emission wavelength (the larger the band gap and the shallower the conduction band minimum (CBM)), the more the electron shortage and the hole excess are likely to occur. Therefore, even in the second regions P2R, P2G, and P2B in which the density of the quantum dots 5 is low (the inorganic compounds are effectively thick and injection of holes having lower mobilities than electrons is suppressed), the carrier balance is easily achieved. Therefore, since the luminance of the second regions P2R, P2G, and P2B can be increased as the emission wavelengths are shorter, the area ratios of the second regions P2R, P2G, and P2B can be reduced. That is, when the emission wavelengths are shorter, the area ratios of the first regions PIR, PIG, and PIB can be increased and the power consumption of the display can be reduced.

Therefore, the area ratio of the first region of the light-emitting element having a shorter emission wavelength is larger than the area ratio of the first region of the light-emitting element having a longer emission wavelength. That is, for example, the area ratio of the first region PIB of the blue light-emitting element 12B having shorter emission wavelength is larger than the area ratios of the first region PIR and the first region PIG of the red light-emitting element 12R and the green light-emitting element 12G having longer light emission wavelengths. The area ratio of the first region PIG of the green light-emitting element 12G having shorter emission wavelength is larger than the area ratio of the first region PIR of the red light-emitting element 12R having longer emission wavelength.

### Second Embodiment

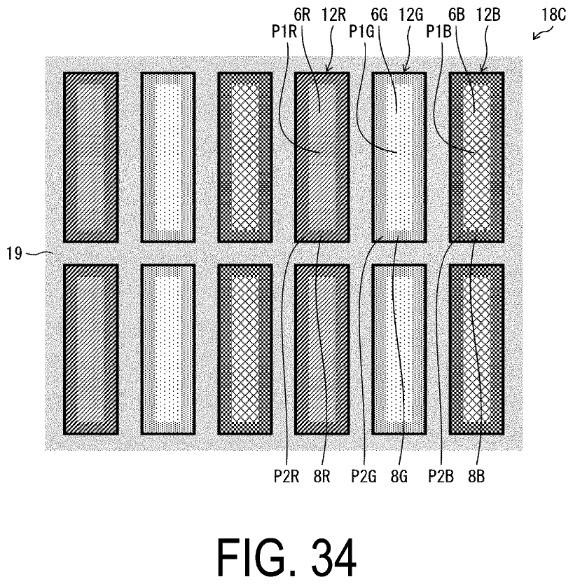

FIG. 34 is a plan view of a display device 18C according to a second embodiment. The same components as the above-described components are denoted by the same reference numerals, and detailed description of the components is not repeated.

The display device 18C includes the substrate 19, and the red light-emitting element 12R, the green light-emitting element 12G, and the blue light-emitting element 12B on the substrate 19. In any one of cross sections along the layering direction of the light-emitting layer 4 of the red light-emitting element 12R, the first region PIR is surrounded by the second region P2R. In any one of cross sections along the layering direction of the light-emitting layer 4 of the green light-emitting element 12G, the first region PIG is surrounded by the second region P2G. In any one of cross sections along the layering direction of the light-emitting layer 4 of the blue light-emitting element 12B, the first region PIB is surrounded by the second region P2B.

The second region P2R surrounds a periphery of the first region PIR when viewed in the layering direction of the light-emitting layer 4. The second region P2G surrounds a periphery of the first region PIG when viewed in the layering direction. The second region P2B surrounds a periphery of the first region PIB when viewed in the layering direction of the light-emitting layer 4.

At the peripheral edges of the red light-emitting element 12R, the green light-emitting element 12G, and the blue light-emitting element 12B, foreign matters or impurities are likely to enter from the cross section of the light-emitting layer 4, and the quantum dots 5 are likely to deteriorate. Therefore, by forming the second regions P2R, P2G, and P2B at the peripheral edges of the red light-emitting element 12R, the green light-emitting element 12G, and the blue light-emitting element 12B, respectively, it is possible to protect the quantum dots 5 from deterioration. Note that although the case where all the light-emitting elements have the above-described structure is illustrated, it does not have to be that way, and as long as at least one light-emitting element has the above-described structure, the above-described effect can be achieved. In addition, it is not necessary to check a plurality of cross sections for the structure in the cross section, and it is enough that the structure can be checked in at least one cross section. This is because the above-described effect is achieved at least in the cross section.

### Third Embodiment

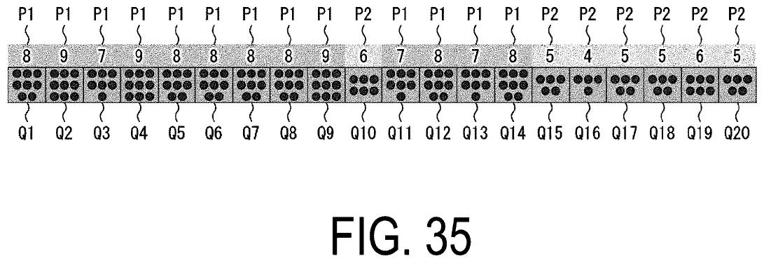

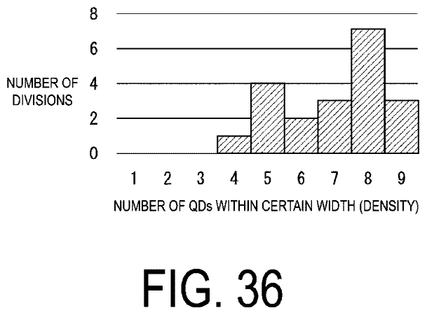

FIG. 35 is a schematic view illustrating the average density of the quantum dots 5 in 20 divided regions Q1 to Q20 of the light-emitting layer 4 of the light-emitting element 1 according to a third embodiment. FIG. 36 is a histogram illustrating the average density of the quantum dots 5 in the light-emitting layer 4. The same components as the above-described components are denoted by the same reference numerals, and detailed description of the components is not repeated.

In any one of cross sections of the light-emitting layer 4 along the layering direction, the range of 600 nm in the direction orthogonal to the layering direction is divided into the 20 divided regions Q1 to Q20 each having the width of 30 nm. Further, with respect to an arbitrarily divided region and another arbitrarily divided region among the divided regions Q1 to Q20, it is determined whether or not a first average density D1 representing the average density of the quantum dots in the arbitrarily divided region and a second average density D2 representing the average density of the quantum dots in the another arbitrarily divided region satisfy D2<0.7×D1. Then, when even one of many combinations of an arbitrarily divided region and another arbitrarily divided region among the divided regions Q1 to Q20 satisfies D2<0.7×D1, the light-emitting layer 4 satisfies a condition 1 of D2<0.7×D1.

In this case, among the divided regions Q1 to Q20 of the light-emitting layer 4, a region of (D1+D2)/2 or more can be regarded as the first region P1, and a region of less than (D1+D2)/2 can be regarded as the second region P2. Alternatively, the density of an arbitrarily determined value may be defined as D3, and a region having a density equal to or higher than D3 may be set as the first region P1 and a region having a density lower than D3 may be set as the second region P2. When calculated by any one of the methods, in the case where the divided regions Q1 to Q20 of the light-emitting layer 4 satisfy the condition 1, the light-emitting layer 4 can be regarded as having the first light-emitting layer 6 and the second light-emitting layer 8 having the density of the quantum dots 5 lower than that of the first light-emitting layer 6. The width of the divided regions Q1 to Q20 may be from 20 nm to 40 nm, which is about two to three times the particle diameter of the quantum dots 5.

Note that the density of the quantum dots 5 is a ratio of a quantum dot area in the divided region having a certain area (the certain width×the layer thickness) obtained by image processing in the cross-sectional TEM image and is classified into about 10 classes from 0 density to a maximum density. In addition, when one quantum dot reaches across the boundary with the adjacent divided region, the area of one quantum dot may be divided by the boundary line and the divided portion may be added to the area of the quantum dot in each region.

In addition, when the average density of the quantum dots 5 in each of the divided regions Q1 to Q20 is divided into 10 classes from 0 to a maximum, a histogram obtained by integrating the number of divided regions for each class satisfies a condition 2 that the histogram has at least two local maximum values.

In this case, among the divided regions Q1 to Q20 of the light-emitting layer 4, a region of (D1+D2)/2 or more can be regarded as the first region P1, and a region of less than (D1+D2)/2 can be regarded as the second region P2. In other words, when the divided regions Q1 to Q20 of the light-emitting layer 4 satisfy the above condition 2, the light-emitting layer 4 can be regarded as having the first light-emitting layer 6 and the second light-emitting layer 8 having the density of the quantum dots 5 lower than that of the first light-emitting layer 6.

In FIG. 35, the average density of the quantum dots 5 in each of the divided regions Q1 to Q20 is indicated by a numerical value.

For example, when considering a combination of the divided region Q2 in which the average density of the quantum dots 5 is 9 and the divided region Q16 in which the average density of the quantum dots 5 is 4 among a large number of combinations of an arbitrarily divided region and another arbitrarily divided region among the divided regions Q1 to Q20, since the first average density D1=9 and the second average density D2=4, 0.7×D1=6.3 is obtained, and the condition 1 of D2<0.7×D1 is satisfied. Since the histogram illustrated in FIG. 36 has two local maximum values of density 5 and density 8, the condition 2 is satisfied. Therefore, the light-emitting layer 4 according to this example can be regarded as having the first light-emitting layer 6 and the second light-emitting layer 8. The threshold value between the first region P1 and the second region P2 is as follows: (D1+D2)/2=6.5.

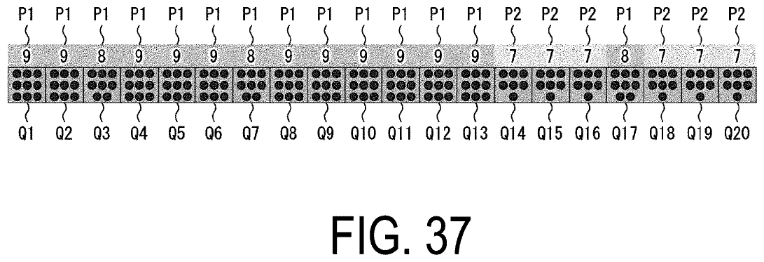

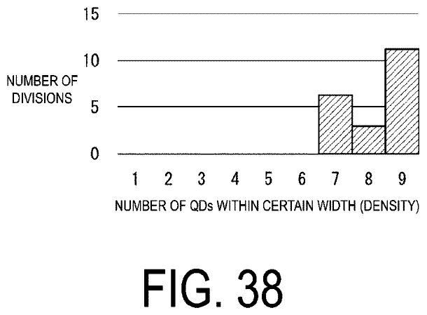

FIG. 37 is a schematic view illustrating an average density of the quantum dots 5 in the light-emitting layer 4 according to another example. FIG. 38 is a histogram illustrating another average density of the quantum dots 5 in the light-emitting layer 4. The same components as the above-described components are denoted by the same reference numerals, and detailed description of the components is not repeated.

In FIG. 37, the average density of the quantum dots 5 in each of the divided regions Q1 to Q20 according to another example is indicated by a numerical value.

For example, when considering a combination of the divided region Q8 in which the average density of the quantum dots 5 is 9 and the divided region Q18 in which the average density of the quantum dots 5 is 7 among a large number of combinations of an arbitrarily divided region and another arbitrarily divided region among the divided regions Q1 to Q20, since the first average density D1=9 and the second average density D2=7, 0.7×D1=6.3 is obtained and the condition 1 of D2<0.7×D1 is not satisfied, but the condition 2 is satisfied because the histogram illustrated in FIG. 38 has two local maximum values of density 7 and density 9. Therefore, the light-emitting layer 4 according to this example can be regarded as having the first light-emitting layer 6 and the second light-emitting layer 8. The threshold value between the first region P1 and the second region P2 is as follows: (D1+D2)/2=8.

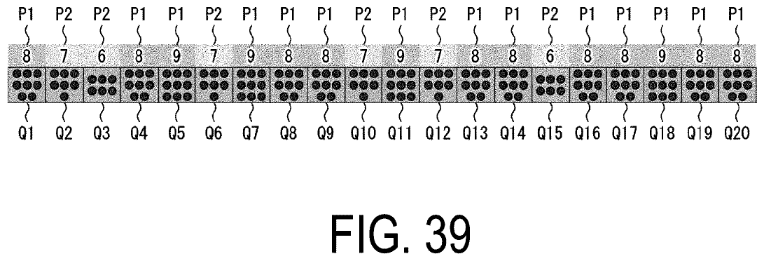

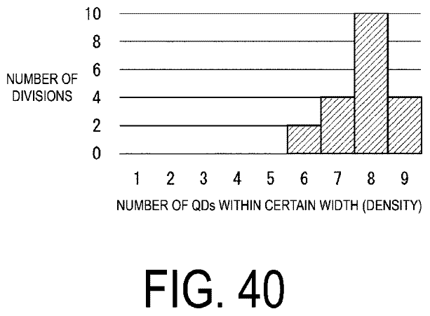

FIG. 39 is a schematic view illustrating the average density of the quantum dots 5 in the light-emitting layer 4 according to still another example. FIG. 40 is a histogram illustrating still another average density of the quantum dots 5 in the light-emitting layer 4. The same components as the above-described components are denoted by the same reference numerals, and detailed description of the components is not repeated.

In FIG. 39, the average density of the quantum dots 5 in each of the divided regions Q1 to Q20 according to still another example is indicated by a numerical value.

The histogram illustrated in FIG. 40 does not satisfy the condition 2 because it has one local maximum value of density 8. However, when considering a combination of the divided region Q5 in which the average density of the quantum dots 5 is 9 and the divided region Q15 in which the average density of the quantum dots 5 is 6 among a large number of combinations of an arbitrarily divided region and another arbitrarily divided region among the divided regions Q1 to Q20, since the first average density D1=9 and the second average density D2=6, 0.7× D1=6.3 is obtained, and the condition 1 of D2<0.7×D1 is satisfied. Therefore, the light-emitting layer 4 according to this example can be regarded as having the first light-emitting layer 6 and the second light-emitting layer 8. The threshold value between the first region P1 and the second region P2 is as follows: (D1+D2)/2=7.5.

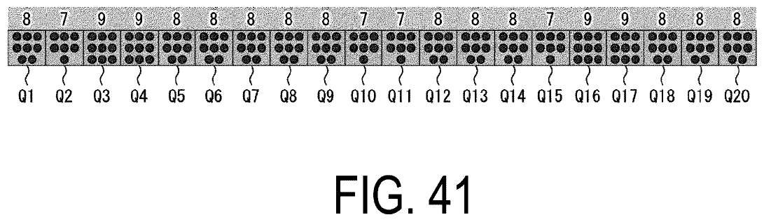

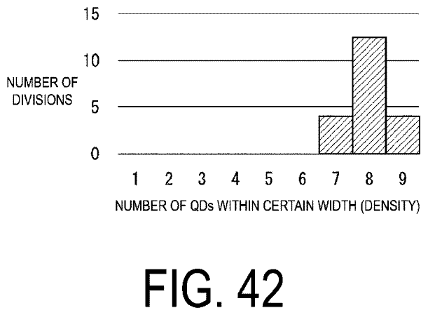

FIG. 41 is a schematic view illustrating still another average density of the quantum dots 5 in the light-emitting layer according to the comparative example. FIG. 42 is a histogram illustrating still another average density of the quantum dots 5 in the light-emitting layer according to the comparative example. The same components as the above-described components are denoted by the same reference numerals, and detailed description of the components is not repeated.

In FIG. 41, the average density of the quantum dots 5 in each of the divided regions Q1 to Q20 according to the comparative example is indicated by a numerical value.

For example, when considering a combination of the divided region Q16 in which the average density of the quantum dots 5 is 9 and the divided region Q2 in which the average density of the quantum dots 5 is 7 among a large number of combinations of an arbitrarily divided region and another arbitrarily divided region among the divided regions Q1 to Q20, since the first average density D1=9 and the second average density D2=7, 0.7×D1=6.3 is obtained and the condition 1 of D2<0.7×D1 is not satisfied. The histogram illustrated in FIG. 42 has one local maximum value of density 8, so the condition 2 is not satisfied. For this reason, the light-emitting layer according to the comparative example cannot be regarded as having the first light-emitting layer 6 and the second light-emitting layer 8.

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in each of the embodiments.

### REFERENCE SIGNS LIST

1 Light-emitting element
2 First electrode
3 Second electrode
4 Light-emitting layer
5 Quantum dot
6 First light-emitting layer
8 Second light-emitting layer
10 Inorganic compound (inorganic matrix)
12R Red light-emitting element
12G Green light-emitting element
12B Blue light-emitting element
18 Display device
P1 First region
P2 Second region
Q1 to Q20 Divided region

1. A light-emitting element comprising:
a first electrode;
a second electrode; and
a light-emitting layer including a plurality of quantum dots between the first electrode and the second electrode,
wherein the light-emitting layer has a first region in which a first light-emitting layer is provided and a second region in which a second light-emitting layer is provided when viewed in a layering direction that is a direction from the first electrode to the second electrode,
a density of the plurality of quantum dots in the second light-emitting layer is lower than a density of the plurality of quantum dots in the first light-emitting layer, and
in the second light-emitting layer, spaces between the plurality of quantum dots are filled with an inorganic matrix.

2. The light-emitting element according to claim 1,
wherein in any one of cross sections of the light-emitting layer along the layering direction, when a range of 600 nm in a direction orthogonal to the layering direction is divided into 20 divided regions each having a width of 30 nm, a first average density D1 of quantum dots in a first divided region of the divided regions and a second average density D2 of quantum dots in a second divided region that is the divided region different from the first divided region satisfy D2<0.7×D1.

3. The light-emitting element according to claim 1,
wherein in any one of cross sections of the light-emitting layer along the layering direction, when a range of 600 nm in a direction orthogonal to the layering direction is divided into 20 divided regions each having a width of 30 nm and an average density of quantum dots in each of the divided regions is divided into 10 classes from 0 to a maximum, a histogram obtained by integrating the number of the divided regions for each class has at least two local maximum values.

4. The light-emitting element according to claim 1,
wherein the first region is surrounded by the second region in any one of cross sections of the light-emitting layer along the layering direction.

5. The light-emitting element according to claim 1,
wherein the second region surrounds a periphery of the first region when viewed in the layering direction.

6. The light-emitting element according to claim 1,
wherein an area of the second region is in a range from 10% to 33% of a total area of the first region and the second region in any one of cross sections of the light-emitting layer along the layering direction.

7. The light-emitting element according to claim 1,
wherein an area filling rate of the quantum dots in the first light-emitting layer is in a range from 63% to 91% in any one of cross sections of the first light-emitting layer along the layering direction.

8. The light-emitting element according to claim 1,
wherein an area filling rate of the quantum dots in the second light-emitting layer is in a range from 30% to 46% in any one of cross sections of the second light-emitting layer along the layering direction.

9. The light-emitting element according to claim 1,
wherein the inorganic matrix is filled in the light-emitting layer.

10. The light-emitting element according to claim 1,
wherein the inorganic matrix includes a continuous film having an area equal to or larger than 1000 nm² in a plane direction intersecting the layering direction.

11. A display device comprising:
a substrate; and
a red light-emitting element, a green light-emitting element, and a blue light-emitting element on the substrate,
wherein each of the red light-emitting element, the green light-emitting element, and the blue light-emitting element is the light-emitting element according to claim 1.

12. The display device according to claim 11,
wherein with respect to any two light-emitting elements of the red light-emitting element, the green light-emitting element, and the blue light-emitting element, when a light-emitting element having a shorter emission wavelength is defined as a short-wavelength element and a longer emission wavelength is defined as a long-wavelength element,
in at least one combination of the short-wavelength element and the long-wavelength element of the display device, and in any one of cross sections of the short-wavelength element or the long-wavelength element along the layering direction, a ratio of an area of the second region to a total area of the light-emitting layer of the short-wavelength element is smaller than a ratio of an area of the second region to a total area of the light-emitting layer of the long-wavelength element.

13. A display device comprising:
a substrate; and
a red light-emitting element, a green light-emitting element, and a blue light-emitting element on the substrate,
wherein only the blue light-emitting element of the red light-emitting element, the green light-emitting element, and the blue light-emitting element is the light-emitting element according to claim 1.

14. A method for manufacturing a light-emitting element including a first electrode, a second electrode, and a light-emitting layer including a plurality of quantum dots between the first electrode and the second electrode, the method comprising:
forming the light-emitting layer having a first region in which a first light-emitting layer is provided and a second region in which a second light-emitting layer is provided when viewed in a layering direction that is a direction from the first electrode to the second electrode,
wherein a density of the plurality of quantum dots in the second light-emitting layer is lower than a density of the plurality of quantum dots in the first light-emitting layer, and
in the second light-emitting layer, spaces between the plurality of quantum dots are filled with an inorganic matrix.

15. The method for manufacturing the light-emitting element according to claim 14,
wherein the forming the light-emitting layer includes:
forming the first light-emitting layer; and
forming the second light-emitting layer.

16. The method for manufacturing the light-emitting element according to claim 15,
wherein the forming the first light-emitting layer is performed after the forming the second light-emitting layer.

17. The method for manufacturing the light-emitting element according to claim 15,
wherein the forming the second light-emitting layer includes:
film-forming a second light-emitting material layer containing a second light-emitting material obtained by mixing a precursor of the inorganic matrix and the quantum dots; and
heating the second light-emitting material layer to form the inorganic matrix from the precursor and obtaining the second light-emitting layer after the film-forming the second light-emitting material layer.

18. A method for manufacturing a display device comprising:
preparing a substrate having a plurality of subpixel regions; and
forming, by the method for manufacturing a light-emitting element according to claim 14, the light-emitting element in each of the plurality of subpixel regions on the substrate.

19. The method for manufacturing the display device according to claim 18,
wherein the forming the light-emitting layer in the forming the light-emitting element includes:
film-forming a first resist layer in each of the plurality of subpixel regions;
film-forming a second light-emitting material layer containing a second light-emitting material obtained by mixing a precursor of the inorganic matrix and the quantum dots after the film-forming the resist layer;
patterning the second light-emitting material layer for each of the plurality of subpixel regions by removing the first resist layer to form the second light-emitting layer after the film-forming the second light-emitting material layer;
performing coating by film-forming a second resist layer on an upper surface of the second light-emitting layer after the patterning the second light-emitting material layer;
forming a first light-emitting layer for each of the plurality of subpixel regions after the performing the coating; and
removing the coating of the second resist layer after the forming the first light-emitting layer.

20. A light-emitting element comprising:
a first electrode;
a second electrode; and
a light-emitting layer including a plurality of quantum dots between the first electrode and the second electrode,
wherein the light-emitting layer has a first region in which a first light-emitting layer is provided and a second region in which a second light-emitting layer is provided when viewed in a layering direction that is a direction from the first electrode to the second electrode,
a density of the plurality of quantum dots in the second light-emitting layer is lower than a density of the plurality of quantum dots in the first light-emitting layer, and
the second light-emitting layer includes an inorganic matrix between the plurality of quantum dots.
